(19) United States
(12) Patent Application Publication
(10) Pub. No.: US 2026/0018539 A1
(43) Pub. Date: Jan. 15, 2026

(54) THREE-DIMENSIONAL INTEGRATED CIRCUIT WITH A CHIPPING AND DELAMINATION BARRIER AND ITS FABRICATION METHOD

(71) Applicant: pSemi Corporation, San Diego, CA (US)

(72) Inventors: Tran Kononova, San Diego, CA (US); Kouassi Sebastien Kouassi, San Diego, CA (US); Doug Hawks, Paulden, AZ (US)

(21) Appl. No.: 19/337,828

(22) Filed: Sep. 23, 2025

Related U.S. Application Data
(63) Continuation of application No. PCT/US2024/021153, filed on Mar. 22, 2024.
(60) Provisional application No. 63/454,490, filed on Mar. 24, 2023.

(51) Int. Cl. H01L 23/00; H10D 88/00

(52) U.S. Cl. CPC H01L 23/562; H01L 24/08; H10D 88/01; H01L 2224/08145

(57) ABSTRACT

A three-dimensional integrated circuit (3D IC) including a first die, a second die, a bonding layer between the first and second dies. The bonding layer bonds the first and second dies. The 3D IC also includes a chipping and delamination barrier (CDB) extending across the first die, the bonding layer, and the second die.

### CROSS REFERENCE TO RELATED APPLICATIONS

This application is a continuation of International Patent Application No. PCT/US2024/021153 filed Mar. 22, 2024 and entitled “A THREE-DIMENSIONAL INTEGRATED CIRCUIT WITH A CHIPPING AND DELAMINATION BARRIER AND ITS FABRICATION METHOD,” which claims priority to and the benefit of U.S. Provisional Patent Application No. 63/454,490 filed Mar. 24, 2023, the entire contents of which are incorporated herein by reference in their entirety.

### TECHNICAL FIELD

The present disclosure relates to a three-dimensional integrated circuit (3D IC), and, more particularly, to structures and fabrication methods of a chipping and delamination barrier (CDB) in the 3D IC.

### BACKGROUND

Chipping and cracking may occur at a bonding interface of a 3D IC during singulation using a mechanical saw tool. The cracking may cause delamination in the 3D IC. The chipping and cracking may spread into deeper layers of dies in the 3D IC and result in defects. Thus, there is a need to avoid or at least mitigate the chipping and/or cracking in the 3D IC.

### SUMMARY

Embodiments of the present disclosure may include integrated circuits and fabrication methods for chipping and delamination barriers in a 3D IC. In one embodiment, a three-dimensional integrated circuit (3D IC) includes a first die, a second die, and a bonding layer between the first and second dies. The bonding layer bonds the first and second dies. The 3D IC also includes a chipping and delamination barrier (CDB) extending across the first die, the bonding layer, and the second die.

In another embodiment, a three-dimensional integrated circuit (3D IC) includes a first die comprising a first metal layer, an active layer, and a backside metal layer; a second die; a bonding layer between the first and second dies, wherein the bonding layer bonding the first and second dies; and a chipping and delamination barrier (CDB) extending from the backside metal layer, through the active layer, to the first metal layer in the first die.

In yet another embodiment, a three-dimensional integrated circuit includes a first die comprising a backside metal layer; a second die comprising first, second, and third metal layers; a bonding layer between the first and second dies, wherein the bonding layer bonding the first and second dies; and a chipping and delamination barrier (CDB) extending from the first metal layer, through the second metal layer, to the third metal layer in the second die.

In another embodiment, a three-dimensional integrated circuit (3D IC) includes a first die comprising a first metal layer, an active layer, and a backside metal layer; a second die comprising a second metal layer; a bonding layer between the first and second dies, wherein the bonding layer bonding the first and second dies; and a chipping and delamination barrier (CDB) extending from the backside metal layer in the first die, through the active layer, the first metal layer, and the bonding layer, to the second metal layer in the second die.

In another embodiment, a method for fabricating a three-dimensional integrated circuit (3D IC) includes forming a first die, the first die comprising a first trench; forming a second die, the second die comprising a second trench; bonding the first and second dies by a bonding layer. The first and second trenches are combined as a chipping and delamination barrier (CDB) extending across the first die, the bonding layer, and the second die.

In yet another embodiment, a method for fabricating a three-dimensional integrated circuit (3D IC) includes forming a first die; forming a second die; bonding the first and second dies by a bonding layer; and forming a trench. The trench extends from a backside metal layer of the first die to a front metal layer of the first side as a chipping and delamination barrier (CDB). In yet another embodiment, the trench extends from the backside metal layer of the first die, across the bonding layer, to a metal layer of the second die, as a chipping and delamination barrier (CDB).

It is to be understood that the foregoing general description and the following detailed description are exemplary and explanatory only and are not restrictive of the invention, as claimed.

### BRIEF DESCRIPTION OF THE DRAWINGS

FIG. 1 illustrates a cross-sectional view of an exemplary 3D IC including a CDB, in accordance with some embodiments.

FIG. 2 illustrates a cross-sectional view of an exemplary 3D IC including a CDB, in accordance with some embodiments.

FIG. 3 illustrates a cross-sectional view of an exemplary 3D IC including a CDB, in accordance with some embodiments.

FIG. 4 illustrates a cross-sectional view of an exemplary 3D IC including a CDB, in accordance with some embodiments.

FIG. 5 illustrates a cross-sectional view of an exemplary 3D IC including a CDB, in accordance with some embodiments.

FIG. 6 illustrates a cross-sectional view of an exemplary 3D IC including a CDB, in accordance with some embodiments.

FIG. 7 illustrates a cross-sectional view of an exemplary 3D IC including a CDB, in accordance with some embodiments.

FIG. 8 illustrates a cross-sectional view of an exemplary 3D IC including a CDB, in accordance with some embodiments.

FIG. 9 illustrates a cross-sectional view of an exemplary 3D IC including a CDB, in accordance with some embodiments.

FIG. 10 is a flow chart of an exemplary method for fabricating a 3D IC including a CDB, in accordance with some embodiments.

FIG. 11 is a flow chart of an exemplary method for fabricating a 3D IC including a CDB, in accordance with some embodiments.

### DETAILED DESCRIPTION

The following disclosure provides many different exemplary embodiments, or examples, for implementing different features of the provided subject matter. Specific simplified examples of components and arrangements are described below to explain the present disclosure. These are, of course, merely examples and are not intended to be limiting. Further, certain features may be omitted from some figures and description for clarity, and it is to be understood that different features from different drawings and/or portions of the specification may be combined in a single embodiment, and the present disclosure contemplates all such embodiments that combine different features from the different drawings and/or portions of the specification. In addition, the present disclosure may repeat reference numerals and/or letters in the various examples. This repetition is for the purpose of simplicity and clarity and does not in itself dictate a relationship between the various embodiments and/or configurations discussed.

A three-dimensional integrated circuit (3D IC) includes a first die, a second die, and a bonding layer between the first and second dies. The bonding layer bonds the first and second dies. The 3D IC also includes a chipping and delamination barrier (CDB) extending across the first die, the bonding layer, and the second die. The CDB may include a trench. The trench may contain nitride and tetraethyl orthosilicate (TEOS). The CDB may strengthen the 3D IC during singulation using, e.g., a mechanical saw tool to avoid or mitigate chipping and cracking in the bonding layer. The CDB may therefore protect the 3D IC from possible defects caused by the chipping and/or cracking. The CDB may also protect the 3D IC from moisture ingress.

In some embodiments, the first die of the 3D IC may include a first outside metal region. The second die may include a second outside metal region. The CDB and the first outside metal region are separated by a first distance equal to or greater than a predefined distance. The CDB and the second outside metal region are separated by a second distance equal to or greater than the predefined distance. The predefined distance may keep possible cracks or defects away from the first die and/or second die. The predefined distance may also help to avoid fault detection of defects during an automated optical inspection (AOI) after the singulation.

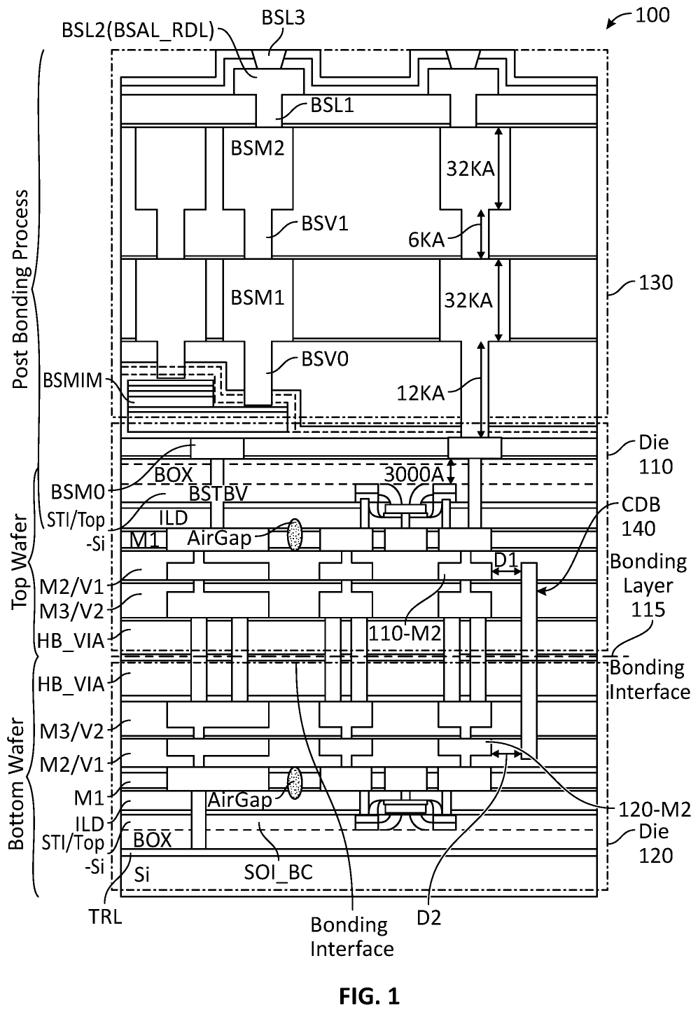

FIG. 1 illustrates a cross-sectional view of an exemplary 3D IC 100 including a chipping and delamination barrier (CDB) 140, in accordance with some embodiments. As shown in FIG. 1, 3D IC 100 includes a die 110, a die 120, bonding layer 115, and CDB 140. Bonding layer 115 bonds dies 110 and 120 together at a bonding interface. Die 110 may also include backside metal regions 130. 3D IC 100 includes a plurality of metal layers in dies 110 and 120 and in metal regions 130. Table 1 illustrates the plurality of metal layers and their exemplary sizes below.

TABLE 1

| | Metal | | Width | THK | Dielectric | Rs |
|---|---|---|---|---|---|---|
| Side | Layer | Description | (um) | (A) | CoCDBant | (mOhm/sq) |
| Backside | BSL3 | BacksidePad | NA | 9K | 4.2/7 | |
| | | opening/L3 | | | | |
| Backside | BSL2 | Backsidealpad | 2.7 | 12K | NA | 30 |
| | | (AL RDL)/L2 | | | | |
| Backside | BSL1 | BacksideWin2/L1 | NA | 12K | 4.1 | |
| Backside | BSM2 | Backside MetalB1 | 1.8 | 12K | 4.2 | 6 |
| Backside | BSV1 | Backside ViaB1 | 0.36 | 6K | 4.2 | |
| Backside | BSM1 | Backside MetalA1 | 1.8 | 12K | 4.1 | 6 |
| Backside | BSMIM* | MIM cap | NA | NA | | |
| Backside | BSV0 | Backside ViaA1 | 0.72 | 12K | 4.2 | |
| Backside | BSM0 | Backside Metal1 | 0.18 | 3.5K | 3.7 | 70 |
| Backside | BSTBV | Backside Through | 0.3 | 3K | 4.2 | |
| | | Box Via | | | | |
| Frontside | Top_M1 | Metal1 | 0.16 | 2.2K | 3.7 | |
| Frontside | Top_V1 | Via1 | 0.19 | 3.2K | 3.7 | |
| Frontside | Top_M2 | Metal2 | 0.2 | 3.2K | 3.7 | 70 |
| Frontside | Top_V2 | Via2 | 0.19 | 3.2K | 3.7 | |
| Frontside | Top_M3 | Metal3 | 0.2 | 3.2K | 3.7 | 70 |
| Frontside | Top_HB | HB_VIA | 1.1 | 9.2K | 4.2 | |
| | VIA | (DBI Layer) | | | | |
| Frontside | Bot_HB | HB_VIA | 1.1 | 9.2k | 4.2 | |
| | VIA | (DBI Layer) | | | | |
| Frontside | Bot_M3 | Metal3 | 0.2 | 3.2K | 3.7 | 70 |
| Frontside | Bot_V2 | Via2 | 0.19 | 3.2K | 3.7 | |
| Frontside | Bot_M2 | Metal2 | 0.2 | 3.2K | 3.7 | 70 |
| Frontside | Bot_V1 | Via1 | 0.19 | 3.2K | 3.7 | |
| Frontside | Bot_M1 | Metal1 | 0.16 | 2.2K | 3.7 | |

As shown in FIG. 1, CDB 140 extends across die 110, bonding layer 115, and die 120. As an example, CDB 140 extends from an M2 layer of die 110, across bonding layer 115, to an M2 layer of die 120. In some embodiments, a CDB may extend from any of an M1 layer, the M2 layer, an M3 layer, and a backside metal layer (e.g., BSM0) in die 110; across bonding layer 115, to any of an M3 layer, the M2 layer, an M1 layer in die 120.

CDB 140 may include a trench. The trench may contain nitride and tetraethyl orthosilicate (TEOS). CDB 140 may strengthen 3D IC 100 when it is under singulation using, e.g., a mechanical saw tool. CDB 140 may therefore avoid or mitigate chipping and cracking in bonding layer 115 or at the bonding interface. CDB may therefore protect 3D IC 100 from possible defects that may be caused by the chipping and/or cracking. CDB 140 may also protect 3D IC 100 from moisture ingress.

In some embodiments, 3D IC 100 may include a plurality of CDBs (not shown) as CDB 140. For example, the plurality of CDBs may be arranged at four sides of 3D IC 100 to protect it from chipping and/or cracking at the four sides. As another example, the plurality of CDBs may be arranged at one, two, or three sides of 3D IC 100 to protect it from chipping and/or cracking at these sides and/or from moisture ingress.

As shown in FIG. 1, die 110 includes a metal region 110-M2 that is at the outside part of die 110. CDB 140 is separated from outside metal region 110-M2 by a distance D1. Distance D1 is equal to or greater than a predefined distance required by, for example, an AOI machine. The AOI machine may scan a region between outside metal region 110-M2 and CDB 140 to determine if there is any defect in 3D IC 100.

As shown in FIG. 1, die 120 includes a metal region 120-M2 that is at the outside part of die 120. CDB 140 is separated from outside metal region 120-M2 by a distance D2. Distance D2 is equal to or greater than the predefined distance required by, for example, the AOI machine. The AOI machine may scan a region between outside metal region 120-M2 and CDB 140 to determine if there is any defect in 3D IC 100.

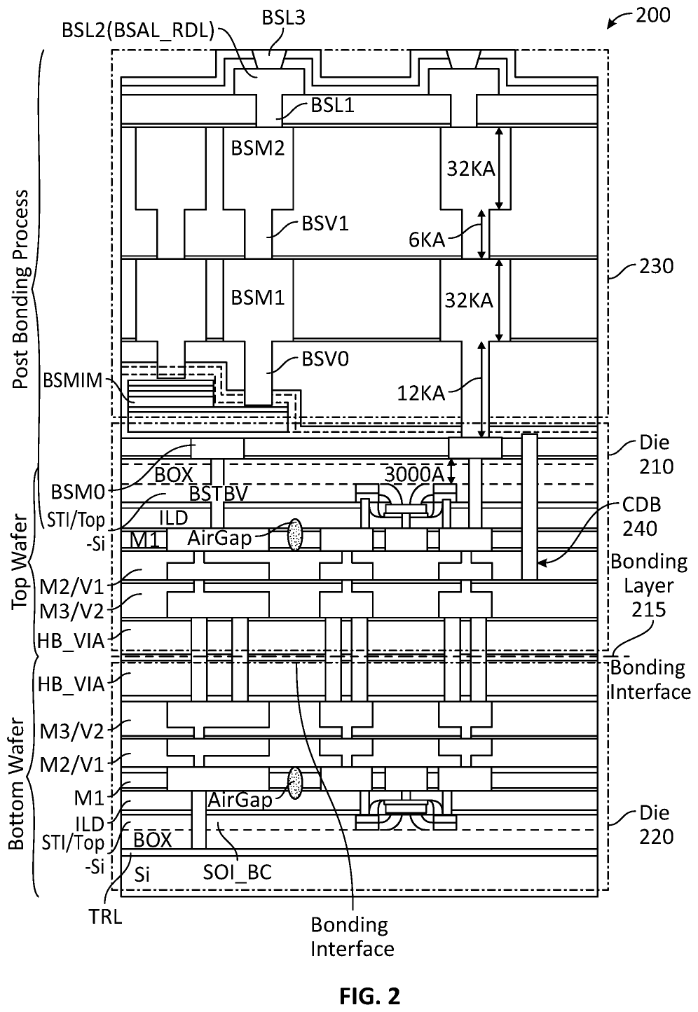

FIG. 2 illustrates a cross-sectional view of an exemplary 3D IC 200 including a CDB 240, in accordance with some embodiments. As shown in FIG. 2, 3D IC 200 includes a die 210, a die 220, bonding layer 215, and CDB 240. Bonding layer 215 bonds dies 210 and 220 together at a bonding interface. Die 210 may also include backside metal regions 230. 3D IC 200 includes a plurality of metal layers in dies 210 and 220 and in metal regions 230. The plurality of metal layers and their exemplary sizes may be referred to Table 1 above.

As shown in FIG. 2, CDB 240 extends from a backside metal layer, across an active layer, to a front metal layer in die 210. As an example, CDB 240 extends from a backside metal layer (e.g., BSM0 (FIG. 2)) in die 210, across an active layer (e.g., BOX (FIG. 2)) to a M2 layer in die 210. In some embodiments, a CDB may extend from any of backside metal layers (e.g., BSM0, BSM1, or BSM2 (FIG. 2)) in die 210; across the active layer (e.g., BOX (FIG. 2)) to any of the M2 layer or an M3 layer in die 210.

CDB 240 may have similar properties and functions as explained above for CDB 140. In some embodiments, CDB 240 may be specifically used to avoid chipping and/or cracking because of an ultra thick metal region within die 210. Therefore, CDB 240 may protect 3D IC 200 from possible defects that may be caused by the chipping and/or cracking during singulation. CDB 240 may also protect 3D IC 200 from moisture ingress.

In some embodiments, 3D IC 200 may include a plurality of CDBs (not shown) as CDB 240. For example, the plurality of CDBs may be arranged at four sides of 3D IC 200 to protect it from chipping and/or cracking at the four sides. As another example, the plurality of CDBs may be arranged at one, two, or three sides of 3D IC 200 to protect it from chipping and/or cracking at these sides and/or from moisture ingress. CDB 240 is separated from an outside metal region of die 210 by a distance D1 (not shown). Distance D1 is equal to or greater than a predefined distance required by, for example, an AOI machine. The AOI machine may scan a region between the outside metal region and CDB 240 to determine if there is any defect in 3D IC 200.

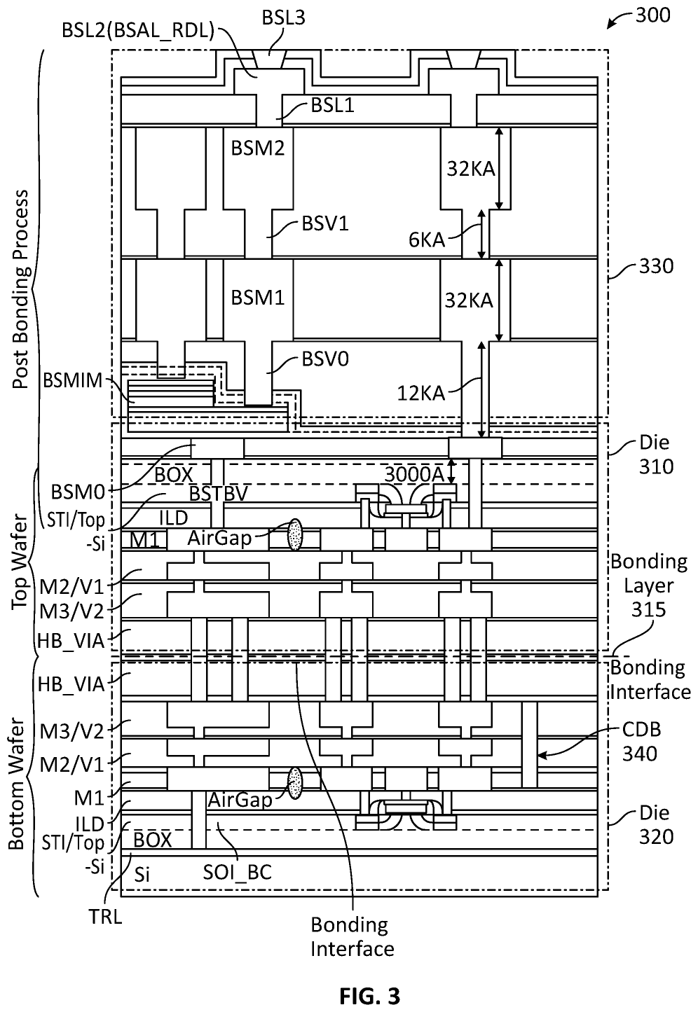

FIG. 3 illustrates a cross-sectional view of an exemplary 3D IC 300 including a CDB 340, in accordance with some embodiments. As shown in FIG. 3, 3D IC 300 includes a die 310, a die 320, bonding layer 315, and CDB 340. Bonding layer 315 bonds dies 310 and 320 together at a bonding interface. Die 310 may also include backside metal regions 330. 3D IC 300 includes a plurality of metal layers in dies 310 and 320 and in metal regions 330. The plurality of metal layers and their exemplary sizes may be referred to Table 1 above.

As shown in FIG. 3, CDB 340 extends from a first metal layer to a second metal layer in die 320. As an example, CDB 340 extends from an M3 layer to an M1 layer in die 320. In some embodiments, a CDB may extend from a first of a plurality of metal layers (not shown) in die 320 to a second of the plurality of metal layers in die 320.

CDB 340 may have similar properties and functions as explained above for CDB 140. Therefore, CDB 340 may protect 3D IC 300 from possible defects that may be caused by the chipping and/or cracking during singulation. CDB 340 may also protect 3D IC 300 from moisture ingress.

In some embodiments, 3D IC 300 may include a plurality of CDBs (not shown) as CDB 340. For example, the plurality of CDBs may be arranged at four sides of 3D IC 300 to protect it from chipping and/or cracking at the four sides. As another example, the plurality of CDBs may be arranged at one, two, or three sides of 3D IC 300 to protect it from chipping and/or cracking at these sides and/or from moisture ingress.

CDB 340 is separated from an outside metal region of die 320 by a distance D2 (not shown). Distance D2 is equal to or greater than a predefined distance required by, for example, an AOI machine. The AOI machine may scan a region between the outside metal region and CDB 340 to determine if there is any defect in 3D IC 300.

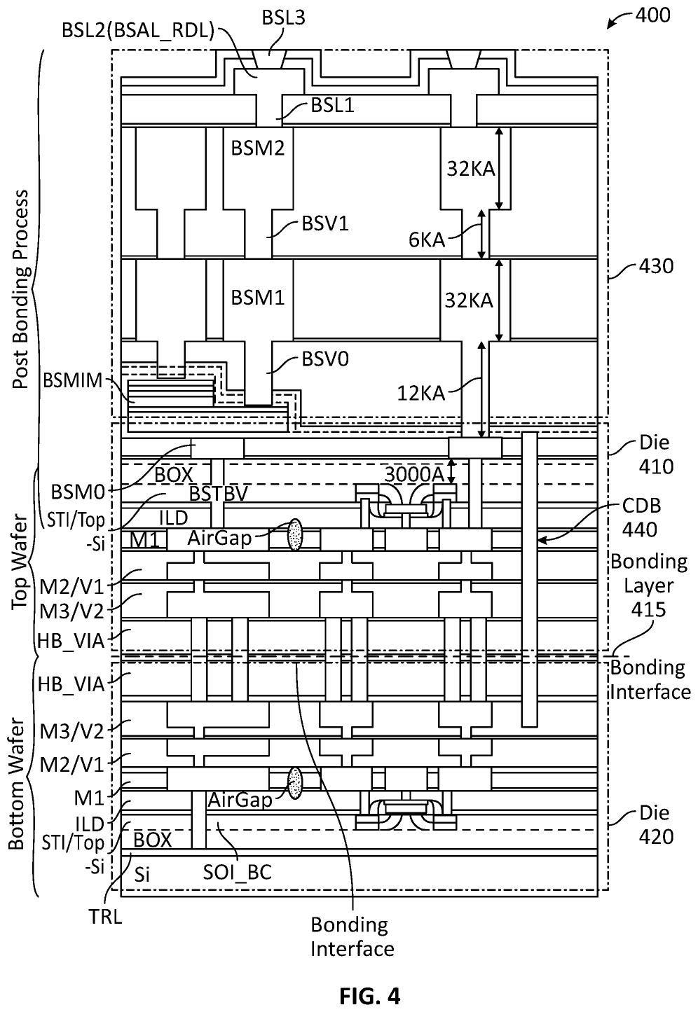

FIG. 4 illustrates a cross-sectional view of an exemplary 3D IC 400 including a CDB 440, in accordance with some embodiments. As shown in FIG. 4, 3D IC 400 includes a die 410, a die 420, bonding layer 415, and CDB 440. Bonding layer 415 bonds dies 410 and 420 together at a bonding interface. Die 410 may also include backside metal regions 430. 3D IC 400 includes a plurality of metal layers in dies 410 and 420 and in metal regions 430. The plurality of metal layers and their exemplary sizes may be referred to Table 1 above.

As shown in FIG. 4, CDB 440 extends across die 410, bonding layer 415, and die 420. As an example, CDB 440 extends from a backside metal layer (e.g., BSM0) of die 410, across bonding layer 415, to an M3 layer of die 420. In some embodiments, a CDB may extend from any of a plurality of backside metal layers (e.g., BSM0, BSM1, BSM2 (FIG. 4)) in die 410; across bonding layer 415, to any of an M3 layer, the M2 layer, an M1 layer in die 420.

CDB 440 may have similar properties and functions as explained above for CDB 140. Therefore, CDB 440 may protect 3D IC 400 from possible defects that may be caused by the chipping and/or cracking during singulation. CDB 440 may also protect 3D IC 400 from moisture ingress.

In some embodiments, 3D IC 400 may include a plurality of CDBs (not shown) as CDB 440. For example, the plurality of CDBs may be arranged at four sides of 3D IC 400 to protect it from chipping and/or cracking at the four sides. As another example, the plurality of CDBs may be arranged at one, two, or three sides of 3D IC 400 to protect it from chipping and/or cracking at these sides and/or from moisture ingress.

CDB 440 is separated from an outside metal region of die 410 by a distance D1 (not shown). Distance D1 is equal to or greater than a predefined distance required by, for example, an AOI machine. The AOI machine may scan a region between the outside metal region and CDB 440 to determine if there is any defect in 3D IC 400.

CDB 440 is separated from an outside metal region of die 420 by a distance D2 (not shown). Distance D2 is equal to or greater than a predefined distance required by, for example, an AOI machine. The AOI machine may scan a region between the outside metal region and CDB 440 to determine if there is any defect in 3D IC 400.

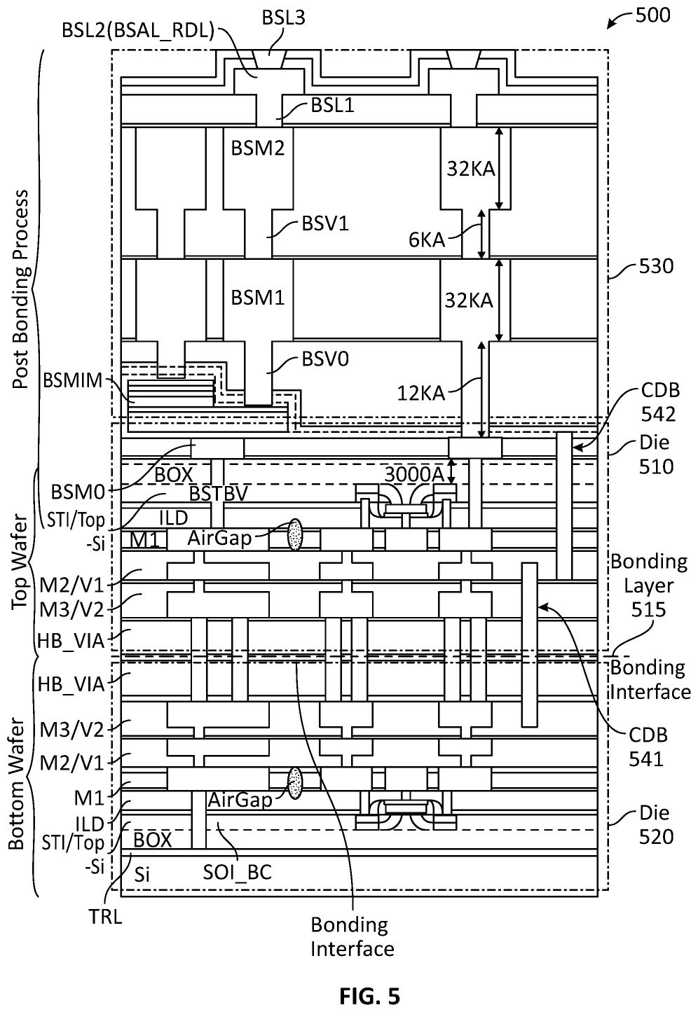

FIG. 5 illustrates a cross-sectional view of an exemplary 3D IC 500 including a CDB 541 and a CDB 542, in accordance with some embodiments. As shown in FIG. 5, 3D IC 500 includes a die 510, a die 520, bonding layer 515, and CDBs 541 and 542. Bonding layer 515 bonds dies 510 and 520 together at a bonding interface. Die 510 may also include backside metal regions 530. 3D IC 500 includes a plurality of metal layers in dies 510 and 520 and in metal regions 530. The plurality of metal layers and their exemplary sizes may be referred to Table 1 above.

CDB 541 in 3D IC 500 (FIG. 5) has structure, properties, and protection functions similar to CDB 140 in 3D IC 100 (FIG. 1), as described above with reference to FIG. 1. CDB 542 in 3D IC 500 (FIG. 5) has structure, properties, and functions similar to CDB 240 in 3D IC 200 (FIG. 2), as described above with reference to FIG. 2.

In some embodiments, 3D IC 500 may include a plurality of CDBs (not shown) as CDB 541 and/or CDB 542. For example, the plurality of CDBs may be arranged at four sides of 3D IC 500 to protect it from chipping and/or cracking at the four sides. As another example, the plurality of CDBs may be arranged at one, two, or three sides of 3D IC 500 to protect it from chipping and/or cracking at these sides and/or from moisture ingress.

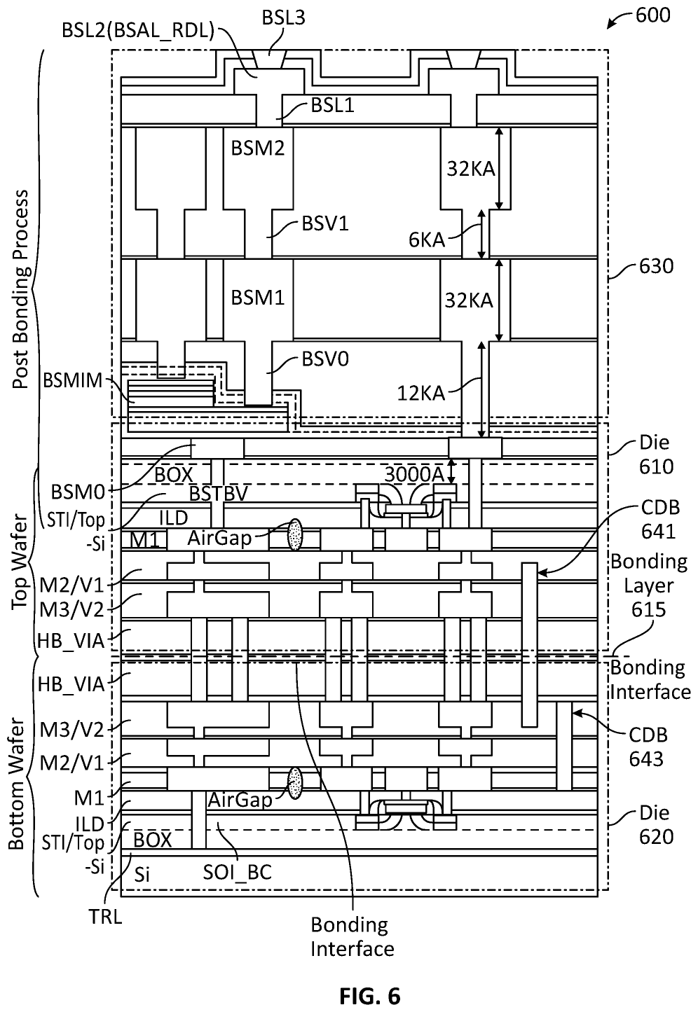

FIG. 6 illustrates a cross-sectional view of an exemplary 3D IC 600 including a CDB 641 and a CDB 643, in accordance with some embodiments. As shown in FIG. 6, 3D IC 600 includes a die 610, a die 620, bonding layer 615, and CDBs 641 and 642. Bonding layer 615 bonds dies 610 and 620 together at a bonding interface. Die 610 may also include backside metal regions 630. 3D IC 600 includes a plurality of metal layers in dies 610 and 620 and in metal regions 630. The plurality of metal layers and their exemplary sizes may be referred to Table 1 above.

CDB 641 in 3D IC 600 (FIG. 6) has structure, properties, and protection functions similar to CDB 140 in 3D IC 100 (FIG. 1), as described above with reference to FIG. 1. CDB 643 in 3D IC 600 (FIG. 6) has structure, properties, and functions similar to CDB 340 in 3D IC 300 (FIG. 3), as described above with reference to FIG. 3.

In some embodiments, 3D IC 600 may include a plurality of CDBs (not shown) as CDB 641 and/or CDB 643. For example, the plurality of CDBs may be arranged at four sides of 3D IC 600 to protect it from chipping and/or cracking at the four sides. As another example, the plurality of CDBs may be arranged at one, two, or three sides of 3D IC 600 to protect it from chipping and/or cracking at these sides and/or from moisture ingress.

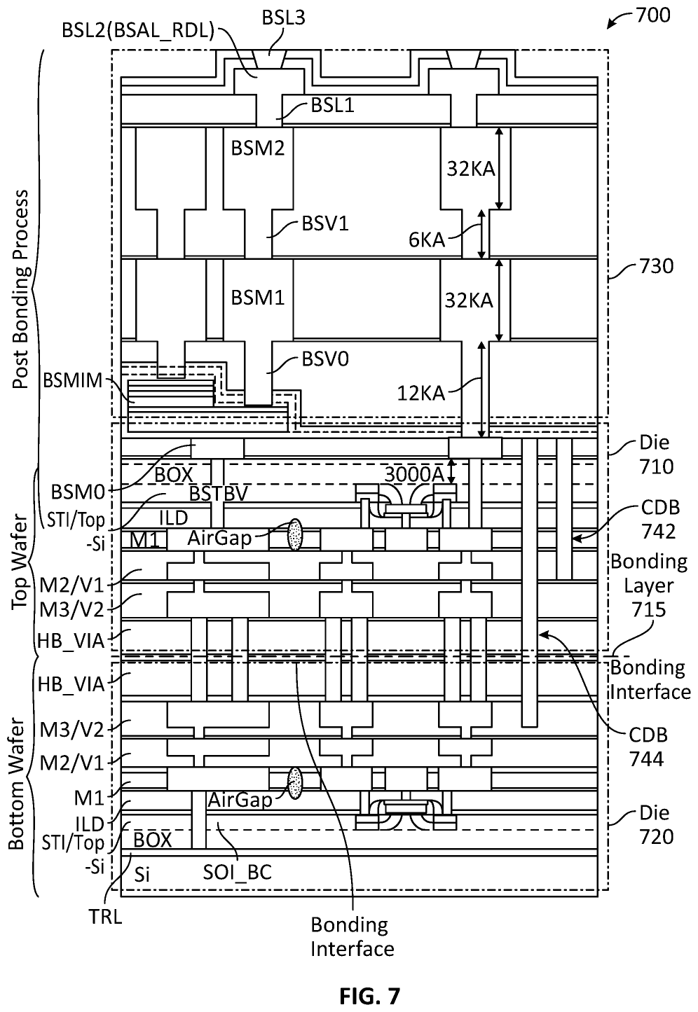

FIG. 7 illustrates a cross-sectional view of an exemplary 3D IC 700 including a CDB 742 and a CDB 744, in accordance with some embodiments. As shown in FIG. 7, 3D IC 700 includes a die 710, a die 720, bonding layer 715, and CDBs 742 and 744. Bonding layer 715 bonds dies 710 and 720 together at a bonding interface. Die 710 may also include backside metal regions 730. 3D IC 700 includes a plurality of metal layers in dies 710 and 720 and in metal regions 730. The plurality of metal layers and their exemplary sizes may be referred to Table 1 above.

CDB 742 in 3D IC 700 (FIG. 7) has structure, properties, and protection functions similar to CDB 240 in 3D IC 200 (FIG. 2), as described above with reference to FIG. 2. CDB 744 in 3D IC 700 (FIG. 7) has structure, properties, and functions similar to CDB 440 in 3D IC 400 (FIG. 4), as described above with reference to FIG. 4.

In some embodiments, 3D IC 700 may include a plurality of CDBs (not shown) as CDB 742 and/or CDB 744. For example, the plurality of CDBs may be arranged at four sides of 3D IC 700 to protect it from chipping and/or cracking at the four sides. As another example, the plurality of CDBs may be arranged at one, two, or three sides of 3D IC 700 to protect it from chipping and/or cracking at these sides and/or from moisture ingress.

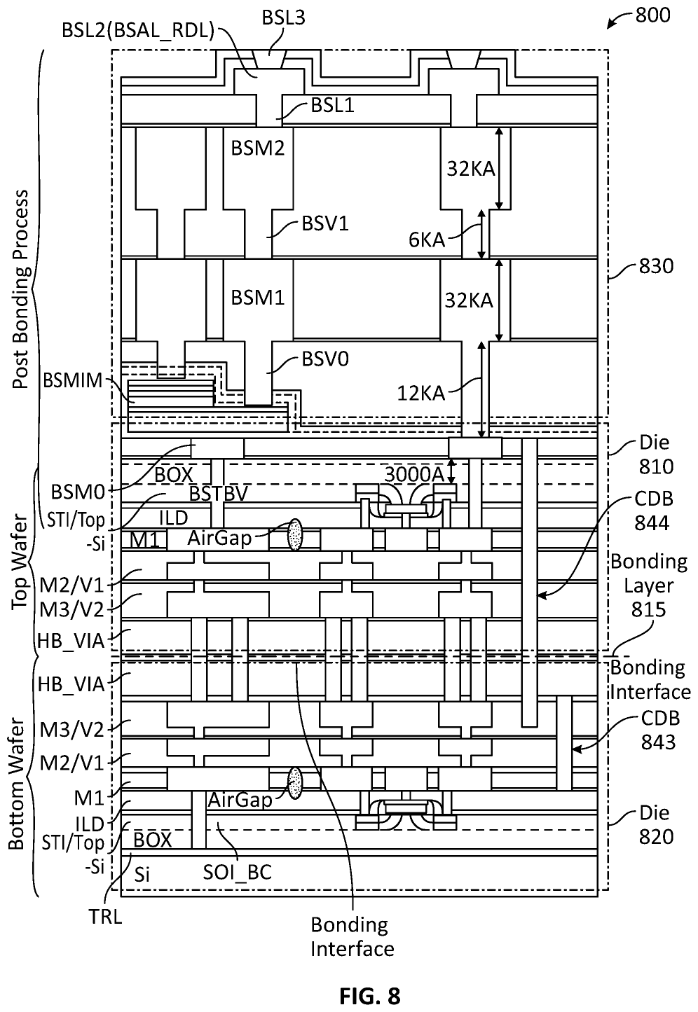

FIG. 8 illustrates a cross-sectional view of an exemplary 3D IC 800 including a CDB 843 and a CDB 844, in accordance with some embodiments. As shown in FIG. 8, 3D IC 800 includes a die 810, a die 820, bonding layer 815, and CDBs 843 and 844. Bonding layer 815 bonds dies 810 and 820 together at a bonding interface. Die 810 may also include backside metal regions 830. 3D IC 800 includes a plurality of metal layers in dies 810 and 820 and in metal regions 830. The plurality of metal layers and their exemplary sizes may be referred to Table 1 above.

CDB 843 in 3D IC 800 (FIG. 8) has structure, properties, and protection functions similar to CDB 340 in 3D IC 300 (FIG. 3), as described above with reference to FIG. 3. CDB 844 in 3D IC 800 (FIG. 8) has structure, properties, and functions similar to CDB 440 in 3D IC 400 (FIG. 4), as described above with reference to FIG. 4.

In some embodiments, 3D IC 800 may include a plurality of CDBs (not shown) as CDB 843 and/or CDB 844. For example, the plurality of CDBs may be arranged at four sides of 3D IC 800 to protect it from chipping and/or cracking at the four sides. As another example, the plurality of CDBs may be arranged at one, two, or three sides of 3D IC 800 to protect it from chipping and/or cracking at these sides and/or from moisture ingress.

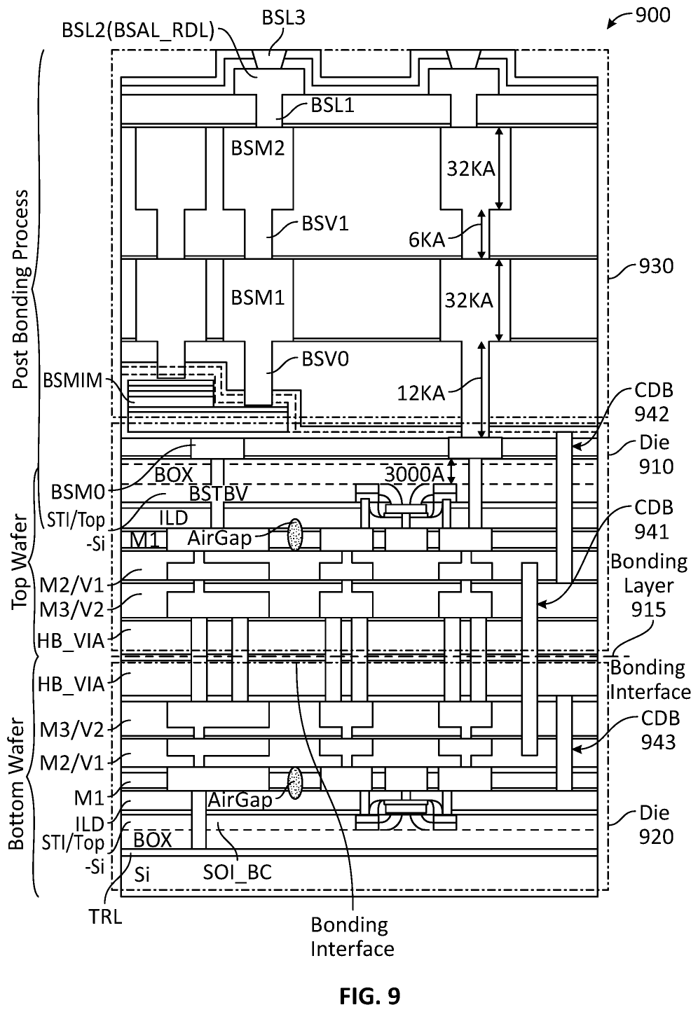

FIG. 9 illustrates a cross-sectional view of an exemplary 3D IC 900 including a CDB 941, a CDB 942, and a CDB 943, in accordance with some embodiments. As shown in FIG. 9, 3D IC 900 includes a die 910, a die 920, bonding layer 915, and CDBs 941, 942, and 943. Bonding layer 915 bonds dies 910 and 920 together at a bonding interface. Die 910 may also include backside metal regions 930. 3D IC 900 includes a plurality of metal layers in dies 910 and 920 and in metal regions 930. The plurality of metal layers and their exemplary sizes may be referred to Table 1 above.

CDB 941 in 3D IC 900 (FIG. 9) has structure, properties, and protection functions similar to CDB 140 in 3D IC 100 (FIG. 1), as described above with reference to FIG. 1. CDB 942 in 3D IC 900 (FIG. 9) has structure, properties, and functions similar to CDB 240 in 3D IC 200 (FIG. 2), as described above with reference to FIG. 2. CDB 943 in 3D IC 900 (FIG. 9) has structure, properties, and protection functions similar to CDB 340 in 3D IC 300 (FIG. 3), as described above with reference to FIG. 3.

In some embodiments, 3D IC 900 may include a plurality of CDBs (not shown) as CDB 941, CDB 942, and/or CDB 943. For example, the plurality of CDBs may be arranged at four sides of 3D IC 900 to protect it from chipping and/or cracking at the four sides. As another example, the plurality of CDBs may be arranged at one, two, or three sides of 3D IC 900 to protect it from chipping and/or cracking at these sides and/or from moisture ingress.

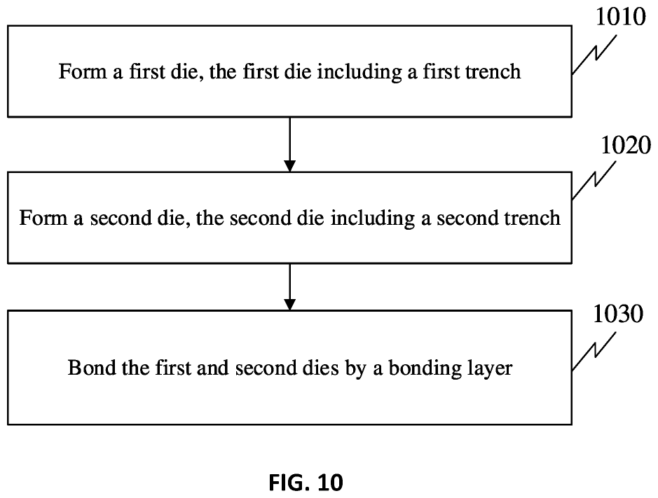

FIG. 10 is a flow chart of an exemplary method 1000 for fabricating a 3D IC including a CDB, in accordance with some embodiments. Method 1000 includes forming a first die, the first die including a first trench (step 1010); forming a second die, the second die including a second trench (step 1020); and bonding the first and second dies by a bonding layer (step 1030).

Step 1010 includes forming a first die, the first die including a first trench. For example, semiconductor manufacturing equipment forms die 110 (FIG. 1) with an upper part of CDB 140 with in the die 110, which is a trench.

Step 1020 includes forming a second die, the second die including a second trench. For example, semiconductor manufacturing equipment forms die 120 (FIG. 1) with a lower part of CDB 140 with in the die 120, which is a trench.

Step 1030 includes bonding the first and second dies by a bonding layer. The first and second trenches are combined as a chipping and delamination barrier (CDB) extending across the first die, the bonding layer, and the second die. For example, semiconductor manufacturing equipment bonds die 110 and die 120 by bonding layer 115. The semiconductor manufacturing equipment also combines the upper part of CDB 140 with in the die 110 and the lower part of CDB 140 with in the die 120 to form CDB 140.

In some embodiments, semiconductor manufacturing equipment forms one or more of 3D ICs 100, 200, 300, 400, 500, 600, 700, 800, and 900 (FIGS. 1-9) in a similar way as described above.

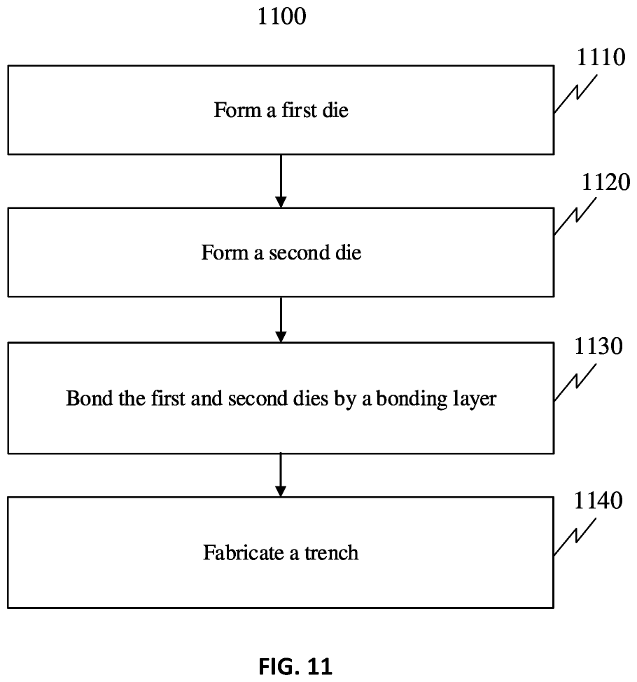

FIG. 11 is a flow chart of an exemplary method 1100 for fabricating a 3D IC including a CDB, in accordance with some embodiments. Method 1100 includes forming a first die (step 1110); forming a second die (step 1120); bonding the first and second dies by a bonding layer (step 1130); and fabricating a trench (step 1140).

Step 1110 includes forming a first die. For example, semiconductor manufacturing equipment forms die 210 (FIG. 2).

Step 1120 includes forming a second die. For example, semiconductor manufacturing equipment forms die 220 (FIG. 2).

Step 1130 includes bonding the first and second dies by a bonding layer. For example, semiconductor manufacturing equipment bonds die 210 and die 220 by bonding layer 215 (FIG. 2).

Step 1140 includes fabricating a trench. For example, semiconductor manufacturing equipment etches a trench extending from a backside metal layer (e.g., BSM0) of die 210 to a metal layer (e.g., M2) of die 210 as CDB 240 (FIG. 2). As another example, semiconductor manufacturing equipment etches a trench extending from a backside metal layer (e.g., BSM0) of die 410 (FIG. 4), across bonding layer 415 (FIG. 4), to a metal layer of die 420 (FIG. 4) as CDB 440 (FIG. 4).

In some embodiments, semiconductor manufacturing equipment forms one or more of 3D ICs 100, 200, 300, 400, 500, 600, 700, 800, and 900 (FIGS. 1-9) in a similar way as described above.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the disclosure disclosed herein. It is also intended that the sequence of steps shown in figures are only for illustrative purposes and are not intended to be limited to any particular sequence of steps. As such, those skilled in the art can appreciate that these steps can be performed in a different order while implementing the same method.

It is appreciated that certain features of the specification, which are, for clarity, described in the context of separate embodiments, may also be provided in combination in a single embodiment. Conversely, various features of the specification, which are, for brevity, described in the context of a single embodiment, may also be provided separately or in any suitable sub-combination or as suitable in any other described embodiments of the specification. Certain features described in the context of various embodiments are not to be considered essential features of those embodiments unless the embodiment is inoperative without those elements.

The embodiments may further be described using the following clauses:
1. A three-dimensional integrated circuit (3D IC), comprising:
   a first die;
   a second die;
   a bonding layer between the first and second dies, wherein the bonding layer bonding the first and second dies; and
   a chipping and delamination barrier (CDB) extending across the first die, the bonding layer, and the second die.
2. The 3D IC of clause 1, wherein the CDB comprises a trench, the trench containing nitride and tetraethyl orthosilicate.
3. The 3D IC of clause 1 or 2, wherein:
   the first die comprising a first outside metal region;
   the second die comprising second outside metal region;
   the CDB and the first outside metal region are separated by a first distance equal to or greater than a predefined distance; and
   the CDB and the second outside metal region are separated by a second distance equal to or greater than the predefined distance.
4. A three-dimensional integrated circuit (3D IC), comprising:
   a first die comprising a first metal layer, an active layer, and a backside metal layer;
   a second die;
   a bonding layer between the first and second dies, wherein the bonding layer bonding the first and second dies; and
   a chipping and delamination barrier (CDB) extending from the backside metal layer, through the active layer, to the first metal layer in the first die.
5. The 3D IC of clause 4, wherein the CDB comprises a trench, the trench containing nitride and tetraethyl orthosilicate.
6. The 3D IC of clause 4 or 5, wherein:
   the first die comprising a first outside metal region in the first metal layer and an outside backside metal region in the backside metal layer;
   the CDB and the first outside metal region are separated by a first distance equal to or greater than a predefined distance; and
   the CDB and the outside backside metal region are separated by a second distance equal to or greater than the predefined distance.
7. A three-dimensional integrated circuit (3D IC), comprising:
   a first die comprising a backside metal layer;
   a second die comprising first, second, and third metal layers;
   a bonding layer between the first and second dies, wherein the bonding layer bonding the first and second dies; and
   a chipping and delamination barrier (CDB) extending from the first metal layer, through the second metal layer, to the third metal layer in the second die.
8. The 3D IC of clause 7, wherein the CDB comprises a trench, the trench containing nitride and tetraethyl orthosilicate.
9. The 3D IC of clause 7 or 8, wherein:
   the first die comprising a first outside metal region;
   the second die comprising second outside metal region;
   the CDB and the first outside metal region are separated by a first distance equal to or greater than a predefined distance; and
   the CDB and the second outside metal region are separated by a second distance equal to or greater than the predefined distance.
10. A three-dimensional integrated circuit (3D IC), comprising:
   a first die comprising a first metal layer, an active layer, and a backside metal layer;
   a second die comprising a second metal layer;
   a bonding layer between the first and second dies, wherein the bonding layer bonding the first and second dies; and
   a chipping and delamination barrier (CDB) extending from the backside metal layer in the first die, through the active layer, the first metal layer, and the bonding layer, to the second metal layer in the second die.
11. The 3D IC of clause 10, wherein the CDB comprises a trench, the trench containing nitride and tetraethyl orthosilicate.
12. The 3D IC of clause 10 or 11, wherein:
   the first die comprising a first outside metal region;
   the second die comprising second outside metal region;
   the CDB and the first outside metal region are separated by a first distance equal to or greater than a predefined distance; and
   the CDB and the second outside metal region are separated by a second distance equal to or greater than the predefined distance.
13. A method for fabricating a three-dimensional integrated circuit (3D IC), the method comprising:
   forming a first die, the first die comprising a first trench;
   forming a second die, the second die comprising a second trench;
   bonding the first and second dies by a bonding layer, wherein the first and second trenches are combined as a chipping and delamination barrier (CDB) extending across the first die, the bonding layer, and the second die.
14. A method for fabricating a three-dimensional integrated circuit (3D IC), the method comprising:
   forming a first die;
   forming a second die;
   bonding the first and second dies by a bonding layer; and
   fabricating a trench,
   wherein:
   the trench extends from a backside metal layer of the first die to a front metal layer of the first side as a first chipping and delamination barrier (CDB), or
   the trench extends from the backside metal layer of the first die, across the bonding layer, to a metal layer of the second die as a second CDB.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In this disclosure, the term “coupled” may also be termed as “electrically coupled”, and the term “connected” may be termed as “electrically connected”. “Coupled” and “connected” may also be used to indicate that two or more elements cooperate or interact with each other.

While embodiments of the present disclosure may address some challenges and provide some benefits, the stated problems and features herein are intended to be examples and not limit the claims or scope of this disclosure. Indeed, the disclosed embodiments may address challenges and provide benefits not explicitly enumerated.

1. A three-dimensional integrated circuit (3D IC), comprising:
a first die;
a second die;
a bonding layer between the first and second dies, wherein the bonding layer bonding the first and second dies; and
a chipping and delamination barrier (CDB) extending across the first die, the bonding layer, and the second die.

2. The 3D IC of claim 1, wherein the CDB comprises a trench, the trench containing nitride and tetraethyl orthosilicate.

3. The 3D IC of claim 2, wherein:
the first die comprising a first outside metal region;
the second die comprising second outside metal region;
the CDB and the first outside metal region are separated by a first distance equal to or greater than a predefined distance; and
the CDB and the second outside metal region are separated by a second distance equal to or greater than the predefined distance.

4. The 3D IC of claim 1, wherein:
the first die comprising a first outside metal region;
the second die comprising second outside metal region;
the CDB and the first outside metal region are separated by a first distance equal to or greater than a predefined distance; and
the CDB and the second outside metal region are separated by a second distance equal to or greater than the predefined distance.

5. A three-dimensional integrated circuit (3D IC), comprising:
a first die comprising a first metal layer, an active layer, and a backside metal layer;
a second die;
a bonding layer between the first and second dies, wherein the bonding layer bonding the first and second dies; and
a chipping and delamination barrier (CDB) extending from the backside metal layer, through the active layer, to the first metal layer in the first die.

6. The 3D IC of claim 5, wherein the CDB comprises a trench, the trench containing nitride and tetraethyl orthosilicate.

7. The 3D IC of claim 6, wherein:
the first die comprising a first outside metal region in the first metal layer and an outside backside metal region in the backside metal layer;
the CDB and the first outside metal region are separated by a first distance equal to or greater than a predefined distance; and
the CDB and the outside backside metal region are separated by a second distance equal to or greater than the predefined distance.

8. The 3D IC of claim 5, wherein:
the first die comprising a first outside metal region in the first metal layer and an outside backside metal region in the backside metal layer;
the CDB and the first outside metal region are separated by a first distance equal to or greater than a predefined distance; and
the CDB and the outside backside metal region are separated by a second distance equal to or greater than the predefined distance.

9. A three-dimensional integrated circuit (3D IC), comprising:
a first die comprising a backside metal layer;
a second die comprising first, second, and third metal layers;
a bonding layer between the first and second dies, wherein the bonding layer bonding the first and second dies; and
a chipping and delamination barrier (CDB) extending from the first metal layer, through the second metal layer, to the third metal layer in the second die.

10. The 3D IC of claim 9, wherein the CDB comprises a trench, the trench containing nitride and tetraethyl orthosilicate.

11. The 3D IC of claim 10, wherein:
the first die comprising a first outside metal region;
the second die comprising second outside metal region;
the CDB and the first outside metal region are separated by a first distance equal to or greater than a predefined distance; and
the CDB and the second outside metal region are separated by a second distance equal to or greater than the predefined distance.

12. The 3D IC of claim 9, wherein:
the first die comprising a first outside metal region;
the second die comprising second outside metal region;
the CDB and the first outside metal region are separated by a first distance equal to or greater than a predefined distance; and
the CDB and the second outside metal region are separated by a second distance equal to or greater than the predefined distance.

13. A three-dimensional integrated circuit (3D IC), comprising:
a first die comprising a first metal layer, an active layer, and a backside metal layer;
a second die comprising a second metal layer;
a bonding layer between the first and second dies, wherein the bonding layer bonding the first and second dies; and
a chipping and delamination barrier (CDB) extending from the backside metal layer in the first die, through the active layer, the first metal layer, and the bonding layer, to the second metal layer in the second die.

14. The 3D IC of claim 13, wherein the CDB comprises a trench, the trench containing nitride and tetraethyl orthosilicate.

15. The 3D IC of claim 14, wherein:
the first die comprising a first outside metal region;
the second die comprising second outside metal region;
the CDB and the first outside metal region are separated by a first distance equal to or greater than a predefined distance; and
the CDB and the second outside metal region are separated by a second distance equal to or greater than the predefined distance.

16. The 3D IC of claim 13, wherein:
the first die comprising a first outside metal region;
the second die comprising second outside metal region;
the CDB and the first outside metal region are separated by a first distance equal to or greater than a predefined distance; and
the CDB and the second outside metal region are separated by a second distance equal to or greater than the predefined distance.

17. A method for fabricating the three-dimensional integrated circuit (3D IC) of claim 1, the method comprising:
forming the first die, the first die comprising a first trench;
forming the second die, the second die comprising a second trench;
bonding the first and second dies by the bonding layer, wherein the first and second trenches are combined as the chipping and delamination barrier (CDB) extending across the first die, the bonding layer, and the second die.

18. A method for fabricating the three-dimensional integrated circuit (3D IC) of claim 5, the method comprising:
forming the first die;
forming the second die;
bonding the first and second dies by the bonding layer; and
fabricating a trench,
wherein the trench extends from the backside metal layer of the first die to the first metal layer as the chipping and delamination barrier (CDB).

19. A method for fabricating the three-dimensional integrated circuit (3D IC) of claim 13, the method comprising:
forming the first die;
forming the second die;
bonding the first and second dies by the bonding layer; and
fabricating a trench,
wherein the trench extends from the backside metal layer of the first die, across the bonding layer, to the second metal layer of the second die as the chipping and delamination barrier (CDB).
